(19) United States
(12) Patent Application Publication
(10) Pub. No.: US 2025/0337376 A1
(43) Pub. Date: Oct. 30, 2025

(54) POWER AMPLIFIER FOR ADJACENT CHANNEL LEAKAGE RATIO ENHANCEMENT OVER WIDE SUPPLY RANGE

(71) Applicant: SKYWORKS SOLUTIONS, INC., Irvine, CA (US)

(72) Inventors: Mohamed Osama Hussein Soliman Abouzeid, Hiawatha, IA (US); Timothy James Mansheim, Hiawatha, IA (US); David Steven Ripley, Cedar Rapids, IA (US); Nathan Lucas Nuzum, Quasqueton, IA (US); Philip John Lehtola, Cedar Rapids, IA (US)

(21) Appl. No.: 19/181,947

(22) Filed: Apr. 17, 2025

Related U.S. Application Data
(60) Provisional application No. 63/638,095, filed on Apr. 24, 2024.

(51) Int. Cl. H03F 3/24; H03F 1/02

(52) U.S. Cl. CPC H03F 3/245; H03F 1/0233; H03F 2200/105; H03F 2200/451

(57) ABSTRACT

A power amplifier system is presented that includes a cascode amplifier circuit configured to amplify a radio frequency signal when powered by a supply voltage and biased by a cascode driving voltage, a supply source configured to provide the supply voltage, and a cascode driving circuit configured to generate the cascode driving voltage based on the supply voltage, the cascode driving circuit including a first stage configured to provide a DC voltage, and a second stage configured to generate the cascode driving voltage that is tracking a level of the supply voltage based on the DC voltage.

### CROSS-REFERENCE TO RELATED APPLICATION

This application claims priority under 35 U.S.C. § 119 (e) to U.S. Provisional Application No. 63/638,095, titled “Power Amplifier for Adjacent Channel Leakage Ratio Enhancement Over Wide Supply Range,” filed on Apr. 24, 2024, which is hereby incorporated by reference in its entirety for all purposes.

### BACKGROUND

### Field

Embodiments of the present disclosure relate to electronic systems, and in particular, to power amplifiers for use in radio frequency (RF) electronics.

### Description of the Related Technology

Power amplifiers are used in radio frequency (RF) communication systems to amplify RF signals for transmission via antennas. It is important to manage the power of RF signal transmissions to prolong battery life and/or provide a suitable transmit power level.

Examples of RF communication systems with one or more power amplifiers include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. An RF signal can have a frequency in the range of about 30 kHz to 300 GHz, such as in the range of about 410 MHz to about 7.125 GHz for certain communications standards.

### SUMMARY

According to at least one aspect of the present disclosure, a power amplifier system is presented, comprising a cascode amplifier circuit configured to amplify a radio frequency signal when powered by a supply voltage and biased by a cascode driving voltage; a supply source configured to provide the supply voltage; and a cascode driving circuit configured to generate the cascode driving voltage based on the supply voltage, the cascode driving circuit including a first stage configured to provide a DC voltage, and a second stage configured to generate the cascode driving voltage that is tracking a level of the supply voltage based on the DC voltage.

In some examples, the cascode amplifier circuit includes a first transistor and a second transistor disposed between the first transistor and a ground, the first transistor being disposed between the second transistor and an output node of the power amplifier system. In some examples, the cascode driving voltage is applied to the first transistor of the cascode amplifier circuit. In some examples, each of the first transistor and the second transistor of the cascode amplifier circuit is a bipolar junction transistor. In some examples, the second stage of the cascode driving circuit includes a current generator including a pair of transistors configured to generate a current tracking the level of the supply voltage. In some examples, the cascode driving voltage is determined by an amount of the generated current in addition to the DC voltage provided by the first stage of the cascode driving circuit. In some examples, the second stage of the cascode driving circuit includes an operational amplifier and a complementary metal oxide semiconductor field effect transistor connected to an output of the operational amplifier to be capable of tracking the level of the supply voltage. In some examples, the second stage includes an adjustable current source that provides power to the operational amplifier. In some examples, the adjustable current source is configured to generate a reference current based on a voltage supplying mode. In some examples, the voltage supplying mode is at least one of an average power tracking (APT) mode and an envelope tracking (ET) mode. In some examples, the adjustable current source is configured to generate a smaller reference current in APT mode than in ET mode.

According to at least one aspect of the present disclosure, a radio frequency module is presented, comprising a packaging board configured to receive a plurality of components; and a power amplifier system implemented on the packaging board, the power amplifier system including a cascode amplifier circuit configured to amplify a radio frequency signal when powered by a supply voltage and biased by a cascode driving voltage, a supply source configured to provide the supply voltage, and a cascode driving circuit configured to generate the cascode driving voltage based on the supply voltage, the cascode driving circuit including a first stage configured to provide a DC voltage, and a second stage configured to generate the cascode driving voltage that is tracking a level of the supply voltage based on the DC voltage.

In some examples, the radio frequency module is a front-end module. In some examples, the cascode amplifier circuit includes a first transistor and a second transistor disposed between the first transistor and a ground, the first transistor being disposed between the second transistor and an output node of the power amplifier system. In some examples, the cascode driving voltage is applied to the first transistor of the cascode amplifier circuit. In some examples, each of the first transistor and the second transistor of the cascode amplifier circuit is a bipolar junction transistor. In some examples, the second stage of the cascode driving circuit includes a current generator including a pair of transistors configured to generate a current tracking the level of the supply voltage. In some examples, the cascode driving voltage is determined by an amount of the generated current in addition to the DC voltage provided by the first stage of the cascode driving circuit. In some examples, the second stage of the cascode driving circuit includes an operational amplifier and a complementary metal oxide semiconductor field effect transistor connected to an output of the operational amplifier to be capable of tracking the level of the supply voltage. In some examples, the second stage includes an adjustable current source that provides power to the operational amplifier. In some examples, the adjustable current source is configured to generate a reference current based on a voltage supplying mode. In some examples, the voltage supplying mode is at least one of an average power tracking (APT) mode and an envelope tracking (ET) mode. In some examples, the adjustable current source is configured to generate smaller reference current in APT mode than in ET mode.

According to at least one aspect of the present disclosure, a mobile device is presented, comprising a transceiver configured to generate a radio frequency signal; and a front end system including a power amplifier system configured to amplify the radio frequency signal, the power amplifier system including a cascode amplifier circuit configured to amplify the radio frequency signal when powered by a supply voltage and biased by a cascode driving voltage, a supply source configured to provide the supply voltage, and a cascode driving circuit configured to generate the cascode driving voltage based on the supply voltage, the cascode driving circuit including a first stage configured to provide a DC voltage; and a second stage configured to generate the cascode driving voltage that is tracking a level of the supply voltage based on the DC voltage.

According to some examples, the cascode amplifier circuit includes a first transistor and a second transistor disposed between the first transistor and a ground, the first transistor being disposed between the second transistor and an output node of the power amplifier system. According to some examples, the cascode driving voltage is applied to the first transistor of the cascode amplifier circuit. According to some examples, each of the first transistor and the second transistor of the cascode amplifier circuit is a bipolar junction transistor. According to some examples, the second stage of the cascode driving circuit includes a current generator including a pair of transistors configured to generate a current tracking the level of the supply voltage. According to some examples, the cascode driving voltage is determined by an amount of the generated current in addition to the DC voltage provided by the first stage of the cascode driving circuit. According to some examples, the second stage of the cascode driving circuit includes an operational amplifier and a complementary metal oxide semiconductor field effect transistor connected to an output of the operational amplifier to be capable of tracking the level of the supply voltage. According to some examples, the second stage includes an adjustable current source that provides power to the operational amplifier. According to some examples, the adjustable current source is configured to generate a reference current based on a voltage supplying mode. According to some examples, the voltage supplying mode is at least one of an average power tracking (APT) mode and an envelope tracking (ET) mode. According to some examples, the adjustable current source is configured to generate smaller reference current in APT mode than in ET mode.

### BRIEF DESCRIPTION OF THE DRAWINGS

FIG. 1 is a schematic diagram of one embodiment of a mobile device;

FIG. 2 is a detailed block diagram of one example of a power amplifier system;

FIG. 3 illustrates a schematic diagram of an example of a power amplifier system;

FIG. 4 illustrates a schematic diagram of an example of a power amplifier system according to an embodiment of the present disclosure;

FIG. 5A illustrates examples of cascode driving voltages of the power amplifier system that are fixed irrespective of the supply voltage;

FIG. 5B illustrates examples of cascode driving voltages of the power amplifier system that are tracking the level of the supply voltage;

FIG. 6 shows a simulation result of the power amplifier system with cascode driving voltages tracking the supply voltage;

FIG. 7 shows another simulation result of the power amplifier system with cascode driving voltages tracking the supply voltage;

FIG. 8 shows examples of various parameters of the power amplifier system for tracking V_{CSD};

FIG. 9A is a schematic diagram of one embodiment of a packaged module;

FIG. 9B is a schematic diagram of a cross-section of the packaged module of FIG. 9A taken along the lines 9B-9B; and

FIG. 10 is a schematic diagram of one embodiment of a phone board.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

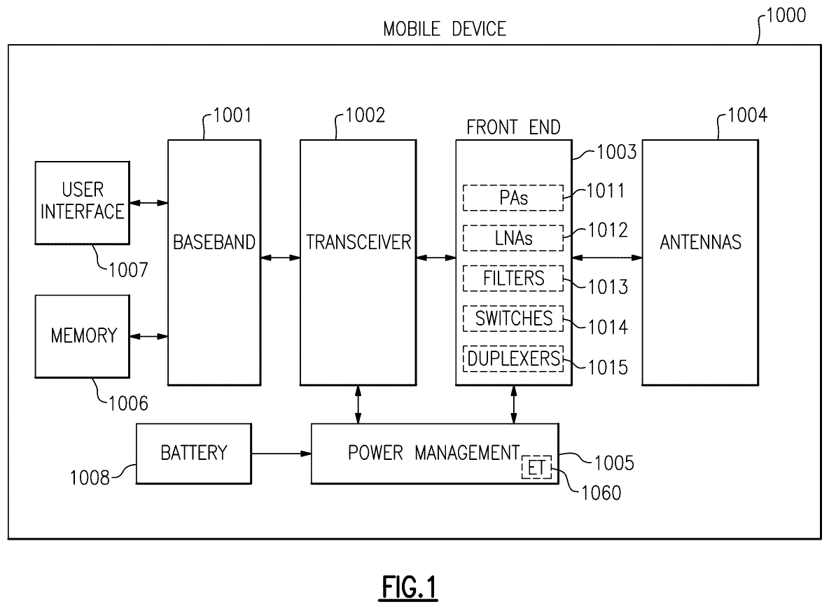

FIG. 1 is a schematic diagram of one example of a mobile device 1000. The mobile device 1000 includes a baseband system 1001, a transceiver 1002, a front end system 1003, antennas 1004, a power management system 1005, a memory 1006, a user interface 1007, and a battery 1008.

The mobile device 1000 can be used communicate using a wide variety of communications technologies, including, but not limited to, 2G, 3G, 4G (including LTE, LTE-Advanced, and LTE-Advanced Pro), 5G, WLAN (for instance, Wi-Fi), WPAN (for instance, Bluetooth and ZigBee), WMAN (for instance, WiMax), and/or GPS technologies.

The transceiver 1002 generates RF signals for transmission and processes incoming RF signals received from the antennas 1004. It will be understood that various functionalities associated with the transmission and reception of RF signals can be achieved by one or more components that are collectively represented in FIG. 1 as the transceiver 1002. In one example, separate components (for instance, separate circuits or dies) can be provided for handling certain types of RF signals.

The front end system 1003 aids in conditioning signals transmitted to and/or received from the antennas 1004. In the illustrated embodiment, the front end system 1003 includes power amplifiers (PAS) 1011, low noise amplifiers (LNAs) 1012, filters 1013, switches 1014, and duplexers 1015. However, other implementations are possible.

For example, the front end system 1003 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 1000 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band and/or in different bands.

The antennas 1004 can include antennas used for a wide variety of types of communications. For example, the antennas 1004 can include antennas associated with transmitting and/or receiving signals associated with a wide variety of frequencies and communications standards.

In certain implementations, the antennas 1004 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 1000 can operate with beamforming in certain implementations. For example, the front end system 1003 can include phase shifters having variable phase controlled by the transceiver 1002. Additionally, the phase shifters may be controlled to provide beam formation and directivity for transmission and/or reception of signals using the antennas 1004. For example, in the context of signal transmission, the phases of the transmit signals provided to the antennas 1004 may be controlled such that radiated signals from the antennas 1004 combine using constructive and destructive interference to generate an aggregate transmit signal exhibiting beam-like qualities with more signal strength propagating in a given direction. In the context of signal reception, the phases may be controlled such that more signal energy is received when the signal is arriving at the antennas 1004 from a particular direction. In certain implementations, the antennas 1004 include one or more arrays of antenna elements to enhance beamforming.

The baseband system 1001 is coupled to the user interface 1007 to facilitate processing of various user input and output (I/O), such as voice and data. The baseband system 1001 provides the transceiver 1002 with digital representations of transmit signals, which the transceiver 1002 processes to generate RF signals for transmission. The baseband system 1001 also processes digital representations of received signals provided by the transceiver 1002. As shown in FIG. 1, the baseband system 1001 is coupled to the memory 1006 to facilitate operation of the mobile device 1000.

The memory 1006 can be used for a wide variety of purposes, such as storing data and/or instructions to facilitate the operation of the mobile device 1000 and/or to provide storage of user information.

The power management system 1005 provides a number of power management functions of the mobile device 1000. The power management system 1005 of FIG. 1 includes an envelope tracker 1060. As shown in FIG. 1, the power management system 1005 receives a battery voltage from the battery 1008. The battery 1008 can be any suitable battery for use in the mobile device 1000, including, for example, a lithium-ion battery.

The mobile device 1000 of FIG. 1 illustrates one example of an RF communication system that can include power amplifier(s) implemented in accordance with one or more features of the present disclosure. However, the teachings herein are applicable to RF communication systems implemented in a wide variety of ways.

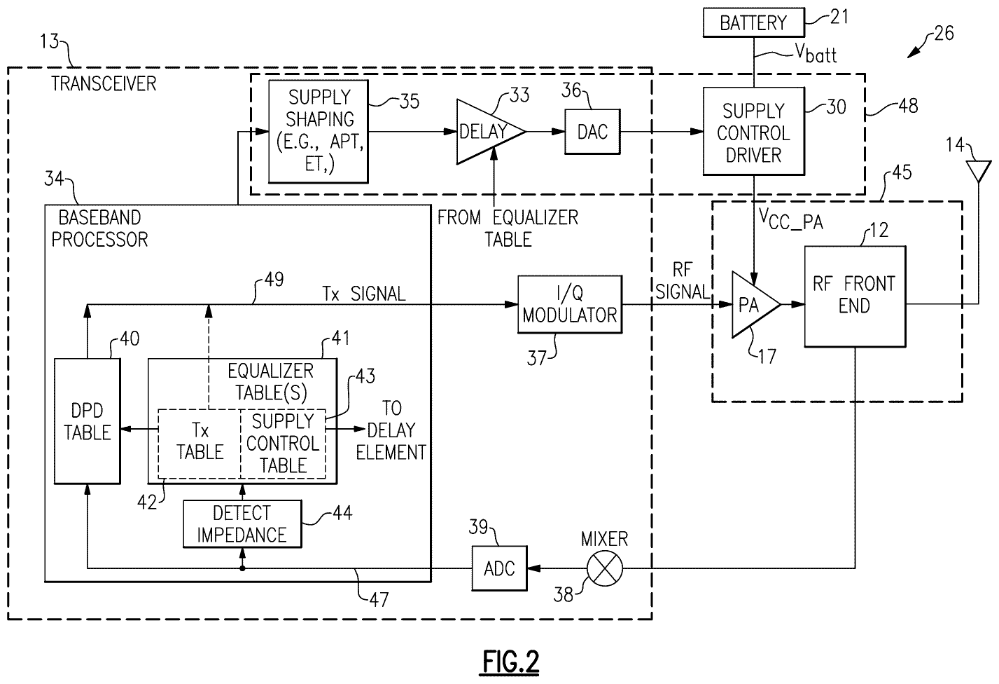

FIG. 2 is a detailed block diagram of one example of a power amplifier system 26. For example, the power amplifier system 26 may be incorporated into the mobile device 1000. The illustrated power amplifier system 26 includes an RF front end 12, an antenna 14, a battery 21, a supply control driver 30, a power amplifier 17, and a transceiver 13. The illustrated transceiver 13 includes a baseband processor 34, a supply shaping block or circuit 35, a delay component 33, a digital-to-analog converter (DAC) 36, a quadrature (I/Q) modulator 37, a mixer 38, and an analog-to-digital converter (ADC) 39. The supply shaping block 35, delay component 33, DAC 36, and supply control driver 30 together form a supply shaping branch 48.

The baseband processor 34 can be used to generate an I-signal and/or a Q-signal, which correspond to signal components of a sinusoidal wave or signal of a desired amplitude, frequency, and phase. For example, the I-signal can be used to represent an in-phase component of the sinusoidal wave and the Q-signal can be used to represent a quadrature component of the sinusoidal wave, which can be an equivalent representation of the sinusoidal wave. In certain implementations, the I and Q-signals can be provided to the I/Q modulator 37 in a digital format. The baseband processor 34 can be any suitable processor configured to process a baseband signal. For instance, the baseband processor 34 can include a digital signal processor, a microprocessor, a programmable core, or any combination thereof. Moreover, in some implementations, two or more baseband processors 34 can be included in the power amplifier system 26.

The I/Q modulator 37 can be configured to receive the I and Q-signals from the baseband processor 34 and to process the I and Q-signals to generate an RF signal. For example, the I/Q modulator 37 can include DACs configured to convert the I and Q-signals into an analog format, mixers for upconverting the I and Q-signals to radio frequency, and a signal combiner for combining the upconverted I and Q-signals into an RF signal suitable for amplification by the power amplifier 17. In certain implementations, the I/Q modulator 37 can include one or more filters configured to filter frequency content of signals processed therein.

The supply shaping block 35 can be used to convert an envelope or amplitude signal associated with the I and Q-signals into a shaped power supply control signal, such as an average power tracking (APT) signal or an envelope tracking (ET) signal, depending on the embodiment. Shaping the envelope signal from the baseband processor 34 can aid in enhancing performance of the power amplifier system 26. In certain implementations, such as where the supplying shaping block is configured to implement an envelope tracking function, the supply shaping block 35 is a digital circuit configured to generate a digital shaped envelope signal, and the DAC 36 is used to convert the digital shaped envelope signal into an analog shaped envelope signal suitable for use by the supply control driver 30. However, in other implementations, the DAC 36 can be omitted in favor of providing the supply control driver 30 with a digital envelope signal to aid the supply control driver 30 in further processing of the envelope signal.

The supply control driver 30 can receive the supply control signal (e.g., an analog shaped envelope signal or APT signal) from the transceiver 13 and a battery voltage V_{batt} from the battery 21, and can use the supply control signal to generate a power amplifier supply voltage V_{CC_PA} for the power amplifier 17 that changes in relation to the transmit signal. The power amplifier 17 can receive the RF transmit signal from the I/Q modulator 37 of the transceiver 13, and can provide an amplified RF signal to the antenna 14 through the RF front end 12. In other cases, a fixed power amplifier supply voltage V_{CC_PA} is provided to the power amplifier 17. In some such embodiments, one or more of the supply shaping block 35, DAC 36, and supply control driver 30 may not be included. In some embodiments, the power amplifier system 26 is capable of performing two or more supply control techniques. For instance, the power amplifier system 26 allows for selection (e.g., via firmware programming or other appropriate mechanism) of two or more of ET, APT, and fixed power supply control modes. In such cases, the baseband processor or other appropriate controller or processor may instruct the supply shaping block 35 to enter into the appropriately selected mode.

The delay component 33 implements a selectable delay in the supply control path. As will be described in further detail, this can be useful in some cases for compensating for non-linearities and/or other potential sources of signal degradation. The illustrated delay component is shown in the digital domain as part of the transceiver 13, and may comprise a FIFO or other type of memory-based delay element. However, the delay component 33 can be implemented in any appropriate fashion, and in other embodiments may be integrated as part of the supply shaping block 35, or may be implemented in the analog domain, after the DAC 36, for example.

The RF front end 12 receives the output of the power amplifier 17, and can include a variety of components including one or more duplexers, switches (e.g., formed in an antenna switch module), directional couplers, and the like.

The directional coupler (not shown) within the RF front end 12 can be a dual directional coupler or other appropriate coupler or other device capable of providing a sensed output signal to the mixer 38. According to certain embodiments, including the illustrated embodiment, the directional coupler is capable of providing both incident and reflected signals (e.g., forward and reverse power) to the mixer 38. For instance, the directional coupler can have at least four ports, which may include an input port configured to receive signals generated by the power amplifier 17, an output port coupled to the antenna 14, a first measurement port configured to provide forward power to the mixer 38, and a second measurement port configured to provide reverse power to the mixer 38.

The mixer 38 can multiply the sensed output signal by a reference signal of a controlled frequency (not illustrated in FIG. 2) so as to downshift the frequency spectrum of the sensed output signal. The downshifted signal can be provided to the ADC 39, which can convert the downshifted signal to a feedback signal 47 in a digital format suitable for processing by the baseband processor 34. As will be discussed in further detail, by including a feedback path between the output of the power amplifier 17 and an input of the baseband processor 34, the baseband processor 34 can be configured to dynamically adjust the I and Q-signals and/or power control signals associated with the I and Q-signals to optimize the operation of the power amplifier system 26. For example, configuring the power amplifier system 26 in this manner can aid in controlling the power added efficiency (PAE) and/or linearity of the power amplifier 32. The mixer 38, ADC 39 and/or other appropriate componentry may generally perform a quadrature (I/Q) demodulation function in some embodiments.

Although the power amplifier system 26 is illustrated as including a single power amplifier, the teachings herein are applicable to power amplifier systems including multiple power amplifiers, including, for example, multi-mode systems and/or multi-mode power amplifier systems.

Additionally, although FIG. 2 illustrates a particular configuration of a transceiver, other configurations are possible, including for example, configurations in which the transceiver 13 includes more or fewer components and/or a different arrangement of components.

As shown, the baseband processor 34 can include a digital pre-distortion (DPD) table 40, an equalizer table 41, and a complex impedance detector 44. The DPD table 40 may be stored in a non-volatile memory (e.g., flash memory, read only memory (ROM), etc.) of the transceiver 34 that is accessible by the baseband processor 34. According to some embodiments, the baseband processor 34 accesses entries in the DPD table 40 to aid in linearizing the power amplifier 17. For instance, the baseband processor 34 selects appropriate entries in the DPD table 40 based on the sensed feedback signal 47, and adjusts the transmit signal accordingly, prior to outputting the transmit signal to the I/Q modulator 37. For example, DPD can be used to compensate for certain nonlinear effects of the power amplifier 17, including, for example, signal constellation distortion and/or signal spectrum spreading. According to certain embodiments including the illustrated embodiment, the DPD table 40 implements memoryless DPD, e.g., where the current output of the DPD corrected transmit signal depends only on the current input.

For the purpose of description, it will be understood that PA of FIG. 2 can be implemented in a number of ways.

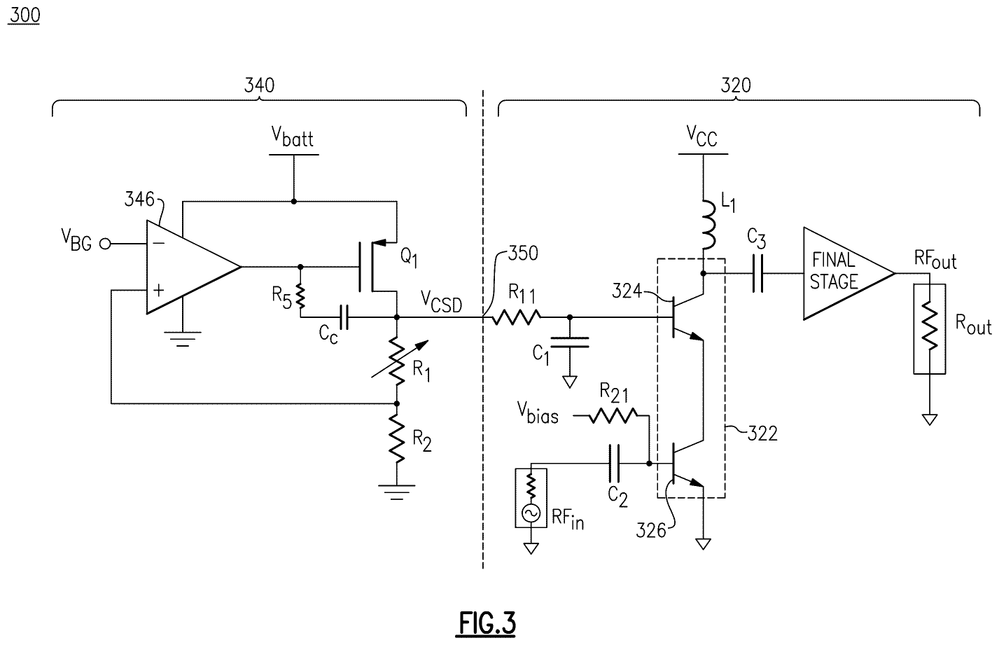

FIG. 3 illustrates a schematic diagram of an example of a power amplifier system 300. In FIG. 3, the power amplifier system 300 may include a power amplifier 320 and a cascode driving circuit 340. The cascode driving circuit 340 may be configured to provide a cascode driving voltage V_{CSD} to the power amplifier 320.

The power amplifier 320 may include a cascode amplifier circuit 322. The cascode amplifier circuit 322 may be configured to amplify a radio frequency signal when powered by a supply voltage V_{CC} based on the cascode driving voltage V_{CSD}. The cascode amplifier circuit 322 may include a first transistor 324 and a second transistor 326. The second transistor 326 may be disposed between the first transistor 324 and a ground. The first transistor 324 may be disposed between the second transistor 326 and an output node RFₒᵤₜ of the power amplifier system 300. In one example, each of the first transistor 324 and the second transistor 326 may be bipolar junction transistors (BJT). In another example, each of the first transistor 324 and the second transistor 326 may be metal oxide semiconductor field effect transistors (MOSFET). Thus, although the transistors are illustrated as BJTs in FIG. 3, the types of the transistors are not limited thereto.

The cascode driving signal generated by the cascode driving circuit 340 may be provided to the first transistor 324 of the cascode amplifier circuit 322. More specifically, the cascode driving voltage V_{CSD} may be provided to a base of the first transistor 324. The base of the first transistor 324 may be connected to a driving node 350 of the cascode driving circuit 340 via resistor R₁₁ and a shunt capacitor C₁. A collector of the first transistor 324 may be connected to the output node RFₒᵤₜ of the power amplifier system 300 via a capacitor C₃ and a final stage of the system 300. Also, the supply voltage V_{CC} provided by the supply source may be applied to cascode amplifier circuit 322 via the collector of the first transistor 324. The collector of the first transistor 324 may be connected to the supply source via an inductor L₁. An emitter of the first transistor 324 may be connected to a collector of the second transistor 326. A radio frequency signal RFᵢₙ may be provided to the cascode amplifier circuit 322 via a base of the second transistor 326. The base of the second transistor 326 may be connected to the input node RFᵢₙ of the power amplifier system 300 that is configured to receive the radio frequency signal, via a capacitor C₂. The capacitor C₂ may be configured to pass an AC signal of the radio frequency signal. The base of the second transistor 326 may be biased by bias voltage V_{bias}. An emitter of the second transistor 326 may be connected to the ground.

In FIG. 3, the cascode driving circuit 340 may include an operational amplifier (OP_AMP) 346 powered by DC power V_{batt}, and a transistor Q₁ connected to an output of the OP_AMP 346. One of the inputs of the OP_AMP 346 may be connected to a node between resistors R₁ and R₂. As shown, resistor R₁ may be a variable resistor. In this example, the cascode driving voltage V_{CSD} induced at the driving node 350 can be calculated as defined by Equation 1.

$${V}_{C S D} = {V}_{B G} * ( 1 + \frac{{R}_{1}}{{R}_{2}} ) \qquad [ Equation 1 ]$$

V_{BG} is another input of the OP_AMP 346.

As can be understood from Equation 1, the cascode driving voltage V_{CSD} only depends on V_{BG}, but does not depend on the level of the supply voltage. In some cases, the supply voltage may vary depending on an operation mode, for example, APT mode or ET mode. If the cascode driving voltage is fixed regardless of the supply voltage, it may cause a restriction on the output range of the power amplifier system. For example, at low levels of the supply voltage (for example, 1.2V), a common base device (for example, the first transistor 324) can saturate early if V_{CSD} is set too high. On the other hand, at high levels of the supply voltage (for example, 5.5V), a common emitter device (for example, the second transistor 326) can saturate early if V_{CSD} is set too low. Therefore, a cascode driver PA has a higher risk of failing calibration with, for example, a V_{CC}=1.2V starting point on calibration.

In order to achieve a maximum output range of the power amplifier system, it is proposed to scale the cascode base voltage V_{CSD} as a function of instantaneous V_{CC}. More specifically, at the lowest supply voltage, the cascode base voltage V_{CSD} will be at its lowest bias voltage to prevent early saturation. At the highest supply voltage, the cascode base voltage V_{CSD} will be at its highest bias voltage to prevent early saturation. That is, Vcascode=Vref*DC gain+V_{CC}*AC gain. Thus, it is beneficial for the cascode driver circuit to track the V_{CC} linearly at high speed operation. The cascode driver circuit may track a 100 MHz V_{CC} signal while minimizing the phase shift according to an embodiment of the present disclosure. The slope of AC gain and DC gain are programmable.

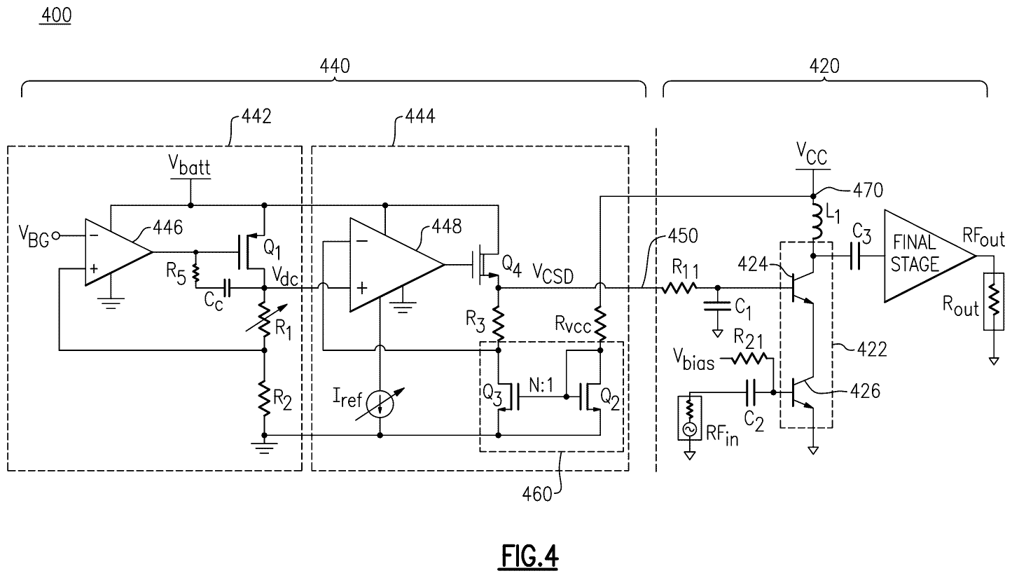

FIG. 4 illustrates a schematic diagram of an example of a power amplifier system 400 according to an embodiment of the present disclosure. The power amplifier system 400 may include a power amplifier 420 and a cascode driving circuit 440. In the power amplifier system 400 shown in FIG. 4, the structure of power amplifier 420 may be similar to the power amplifier 320 described in FIG. 3.

More specifically, the power amplifier 420 may include a cascode amplifier circuit 422. The cascode amplifier circuit 422 may be configured to amplify a radio frequency signal when powered by a supply voltage V_{CC} and biased by the cascode driving voltage V_{CSD}. The cascode amplifier circuit 422 may include a first transistor 424 and a second transistor 426. The second transistor 426 may be disposed between the first transistor 424 and a ground. Thus, the second transistor 426 may be referred to as the common emitter transistor. The first transistor 424 may be disposed between the second transistor 426 and an output node RFₒᵤₜ of the power amplifier system 400. In one example, each of the first transistor 424 and the second transistor 426 may be bipolar junction transistors (BJT). In another example, each of the first transistor 424 and the second transistor 426 may be metal oxide semiconductor field effects transistor (MOSFET). Thus, although the transistors are illustrated as BJTs in FIG. 4, the types of the transistors are not limited thereto.

The cascode driving signal generated by the cascode driving circuit 440 may be provided to the first transistor 424 of the cascode amplifier circuit 422. More specifically, the cascode driving voltage V_{CSD} may be provided to a base of the first transistor 424. The base of the first transistor 424 may be connected to a connecting node 450 of the cascode driving circuit 440 via resistor R₁₁ and a shunt capacitor C₁. The first transistor 424 may be referred to as the common base transistor. A collector of the first transistor 424 may be connected to the output node RFₒᵤₜ of the power amplifier system 400 via a capacitor C₃ and a final stage of the system 400. Also, the supply voltage V_{CC} provided by the supply source may be applied to cascode amplifier circuit 422 via the collector of the first transistor 424. The collector of the first transistor 424 may be connected to the supply source via an inductor L₁. An emitter of the first transistor 424 may be connected to a collector of the second transistor 426. A radio frequency signal RFᵢₙ may be provided to the cascode amplifier circuit 422 via a base of the second transistor 426. The base of the second transistor 426 may be connected to the input node RFᵢₙ of the power amplifier system 400 that is configured to receive the radio frequency signal, via a capacitor C₂. The capacitor C₂ may be configured to pass an AC signal of the radio frequency signal. The base of the second transistor 426 may be biased by bias voltage V_{bias}. An emitter of the second transistor 426 may be connected to the ground.

The cascode driving circuit 440 may include a first stage 442 and a second stage 444. The first stage 442 of the cascode driving circuit 440 may be configured to generate a DC voltage to be provided to the second stage 444. The first stage 444 may include an operational amplifier (OP_AMP) 446 powered by DC power V_{batt}, and a transistor Q₁ connected to an output of the OP_AMP 446. The OP_AMP 466 included in the first stage 442 may be referred to as a first OP_AMP 446. The transistor Q₁ may be a p-type MOSFET. The transistor Q₁ included in the first stage 442 may be referred to as a first CMOS transistor Q₁. A source of the transistor Q₁ may be connected to the DC power V_{batt}, and a gate of the transistor Q₁ may be connected to the output of the OP_AMP 446. The gate of the transistor Q₁ may be connected to a drain of the transistor Q₁ via a capacitor C_{C} and a resistor R₅. One of the inputs of the OP_AMP 446 may be connected to a node between resistors R₁ and R₂. As shown, resistor R₁ may be a variable resistor. In this embodiment, the DC voltage may depend on a preset input voltage V_{BG} and a resistance ratio between the resistors R₁ and R₂. The first stage 442 of the cascode driving circuit 440 may be similar to the cascode driving circuit 340 shown in FIG. 3.

The second stage 444 of the cascode driving circuit 440 may be configured to generate the cascode driving voltage V_{CSD} that is tracking a level of the supply voltage. The second stage 444 may output the cascode driving voltage V_{CSD} using the DC voltage provided by the first stage 442, but will have almost no impact from the DC settings of the first stage 442. The second stage 444 may include an OP_AMP 448 and a transistor Q₄ connected to an output of the OP_AMP 448. The OP_AMP 448 included in the second stage 444 may be referred to as second OP_AMP 448. The transistor Q₄ may be an n-type MOSFET. The transistor Q₄ included in the second stage 444 may be referred to as a second CMOS transistor Q₄. A gate of the second CMOS transistor Q₄ may be connected to the output of the second OP_AMP 448, and a drain of the second CMOS transistor Q₄ may be connected to the DC power V_{batt}. A source of the second CMOS transistor Q₄ may be connected to a driving node 450 which provides the cascode driving voltage V_{CSD} to the power amplifier 420. The second OP_AMP 448 may be powered by the DC power V_{batt} and an adjustable current source I_{ref}. One of the inputs of the second OP_AMP 448 may be connected to the drain of the first CMOS transistor Q₁.

The second stage 444 may include a current generator 460. The current generator 460 may be configured to generate a current tracking the level of the supply voltage. The current generator 460 may include a pair of transistors Q₂ and Q₃. In this embodiment, each of the transistors Q₂ and Q₃ may be an n-type MOSFET. A current flowing through the transistor Q₂ may be mirrored to the paired transistor Q₃, but the value of current may be amplified by a preconfigured ratio N. A drain of transistor Q₂ may be connected to its gate. The drain of the transistor Q₂ may be connected to a detecting node 470 via a resistor R_{vcc}. Thus, the current flowing through the transistor Q₂ may depend on the level of the supply voltage. The other input of the second OP_AMP 448 may be connected to a drain of the paired transistor Q₃. The drain of the paired transistor Q₃ may be connected to the driving node 450 via a resistor R₃. Thus, the current induced in the paired transistor Q₃ may determine the cascode driving voltage V_{CSD} to be multiplied by resistance of R₃ in addition to the DC voltage provided by the first stage 442.

According to an embodiment of the present disclosure, the cascode driving voltage V_{CSD} may be calculated as defined by Equation 2.

$${V}_{C S D} = {V}_{B G} * ( 1 + \frac{{R}_{1}}{{R}_{2}} ) + ( V C C - {V}_{gsQ 2} ) * \frac{N * {R}_{3}}{{R}_{V C C}} \qquad [ Equation 2 ]$$

In Equation 2, V_{gsQ2} is a voltage induced between the gate and the source of the transistor Q₂.

The adjustable current source I_{ref} may provide a negative power to the second OP_AMP 448. The adjustable current source I_{ref} may be configured to generate a reference current based on a voltage supplying mode. The voltage supplying mode may be at least one of an average power tracking (APT) mode and an envelope tracking (ET) mode. According to an embodiment, ET mode may require high bandwidth (BW), and therefore, I_{ref} may be fully turned on. On the other hand, APT mode may not require high BW, and therefore I_{ref} may be partially turned on in this case. Thus, the adjustable current source I_{ref} may be configured to generate a smaller reference current in APT mode than in ET mode.

According to embodiments of the present disclosure, DC settings in the first stage can be isolated from AC settings in the second stage of the cascode driving circuit. DC programmability can be achieved without degrading power consumption. Furthermore, low power in the first stage can be used to set the DC settings for the second stage of the cascode driving circuit. The power consumption can be controlled based on bandwidth requirements, for example in ET mode or APT mode, using the adjustable current source I_{ref}. Moreover, it is possible to easily stabilize the second stage without the requirement for high gain settings. Depletion NMOS transistors (for example, for the second CMOS transistor Q₄) can be used to maximize the output range of the power amplifier system 400.

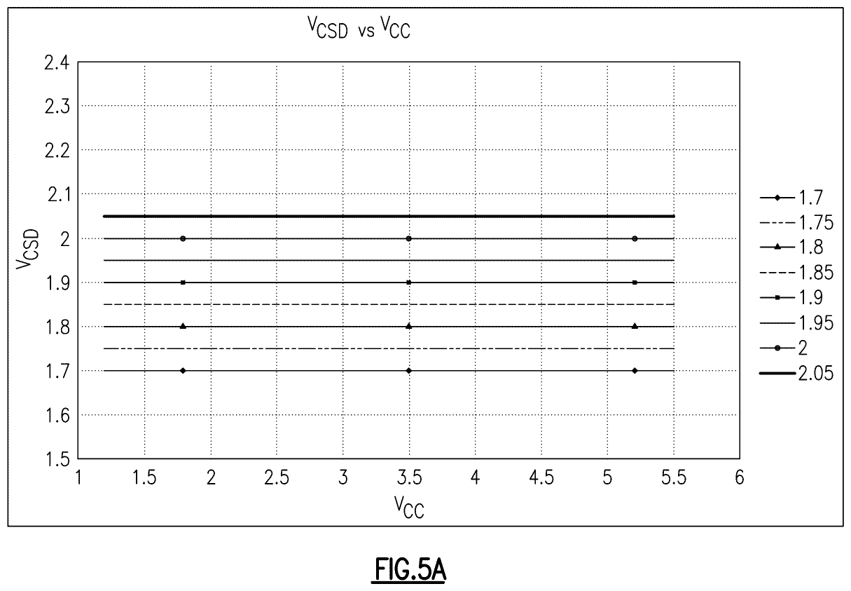

FIG. 5A illustrates examples of a cascode driving voltage of the power amplifier system that are fixed regardless of the supply voltage. FIG. 5B illustrates examples of a cascode driving voltage of the power amplifier system that are tracking the level of supply voltage. As shown in FIG. 5A, once the V_{BG} is determined, the cascode driving voltage V_{CSD} is fixed regardless of the supply voltage. On the other hand, in FIG. 5B, the cascode driving voltage V_{CSD} can linearly track the level of the supply voltage.

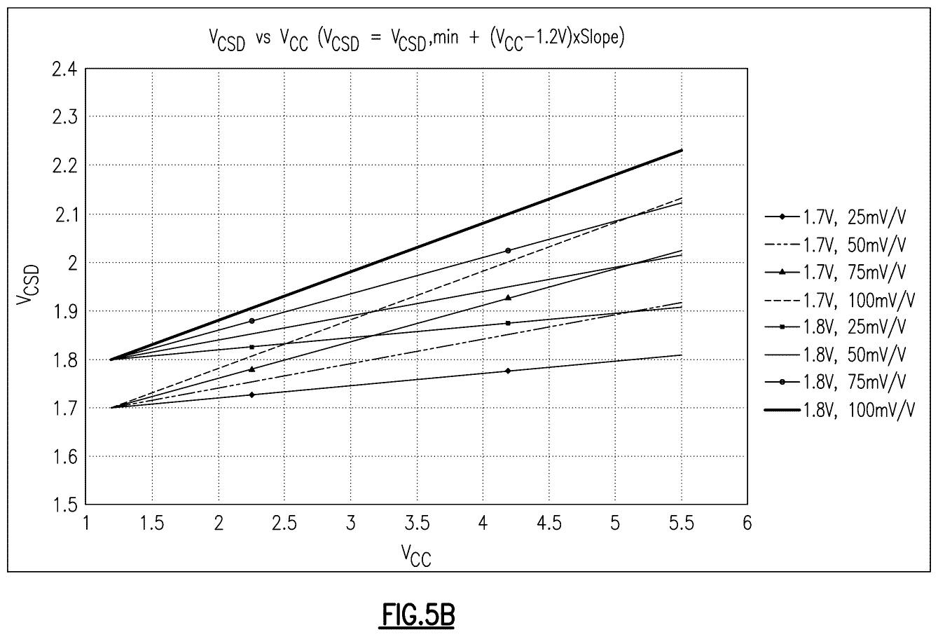

FIG. 6 shows a simulation result of the power amplifier system with the cascode driving voltage tracking the supply voltage. According to the result shown in FIG. 6, it is possible to save between about 4 to 8 mA of current in APT mode which does not require fast V_{CC} tracking.

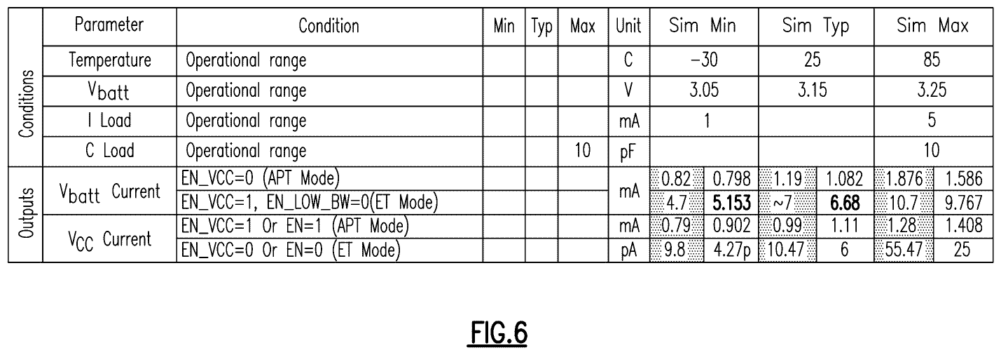

FIG. 7 shows another simulation result of the power amplifier system with the cascode driving voltage tracking the supply voltage. According to the result shown in FIG. 7, the cascode driving voltage capable of tracking the supply voltage ultimately results in a much better result that enables the power amplifier system to reach to the target Adjacent Channel Leakage Ratio (ACLR).

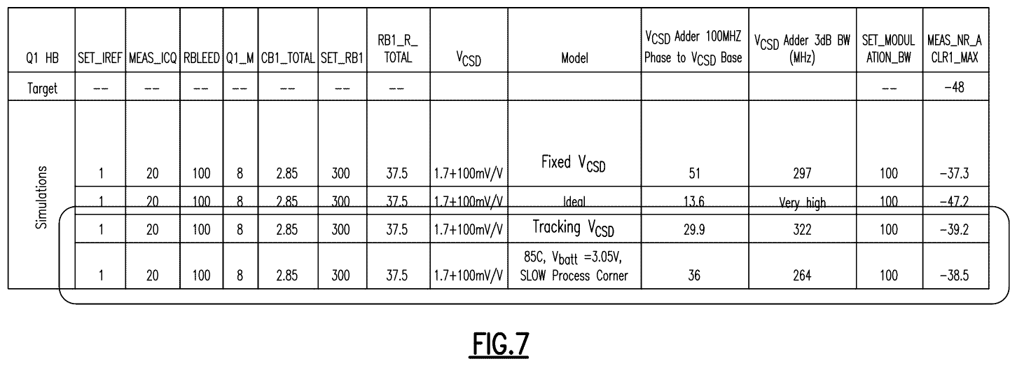

FIG. 8 shows examples of various parameters of the power amplifier system for tracking V_{CSD}.

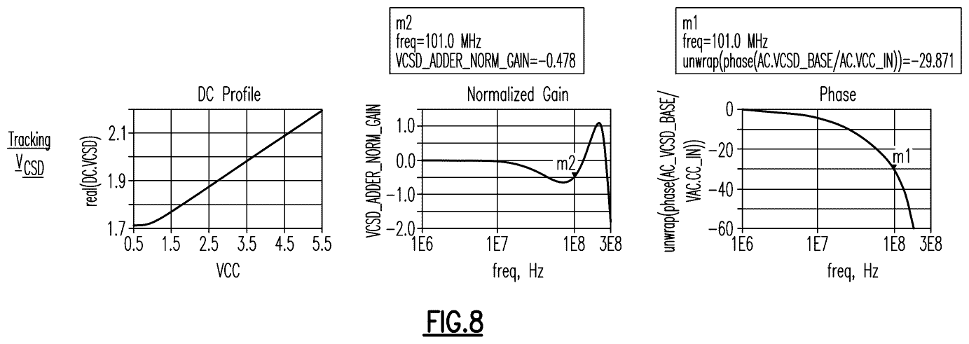

FIG. 9A is a schematic diagram of one embodiment of a packaged module 900. FIG. 9B is a schematic diagram of a cross-section of the packaged module 900 of FIG. 9A taken along the lines 9B-9B.

The packaged module 900 includes an IC or die 901, surface mount components 903, wirebonds 908, a package substrate 920, and an encapsulation structure 940. The package substrate 920 includes pads 906 formed from conductors disposed therein. Additionally, the die 901 includes pads 904, and the wirebonds 908 have been used to electrically connect the pads 904 of the die 901 to the pads 906 of the package substrate 901.

The die 901 includes a power amplifier system, which can be implemented in accordance with any of the embodiments herein.

The packaging substrate 920 can be configured to receive a plurality of components such as the die 901 and the surface mount components 903, which can include, for example, surface mount capacitors and/or inductors.

As shown in FIG. 9B, the packaged module 900 is shown to include a plurality of contact pads 932 disposed on the side of the packaged module 900 opposite the side used to mount the die 901. Configuring the packaged module 900 in this manner can aid in connecting the packaged module 900 to a circuit board such as a phone board of a wireless device. The example contact pads 932 can be configured to provide RF signals, bias signals, power low voltage(s) and/or power high voltage(s) to the die 901 and/or the surface mount components 903. As shown in FIG. 9B, the electrical connections between the contact pads 932 and the die 901 can be facilitated by connections 933 through the package substrate 920. The connections 933 can represent electrical paths formed through the package substrate 920, such as connections associated with vias and conductors of a multilayer laminated package substrate.

In some embodiments, the packaged module 900 can also include one or more packaging structures to, for example, provide protection and/or facilitate handling of the packaged module 900. Such a packaging structure can include an overmold or encapsulation structure 940 formed over the packaging substrate 920 and the components and die(s) disposed thereon.

It will be understood that although the packaged module 900 is described in the context of electrical connections based on wirebonds, one or more features of the present disclosure can also be implemented in other packaging configurations, including, for example, flip-chip configurations.

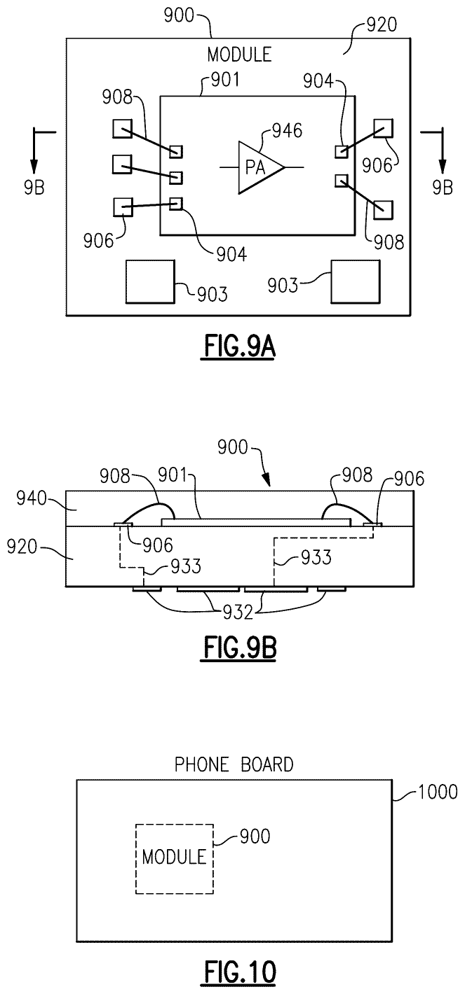

FIG. 10 is a schematic diagram of one embodiment of a phone board 800. The phone board 800 includes the module 900 shown in FIGS. 9A-9B attached thereto. Although not illustrated in FIG. 10 for clarity, the phone board 800 can include additional components and structures.

Some of the embodiments described above have provided examples in connection with wireless devices or mobile phones. However, the principles and advantages of the embodiments can be used for any other systems or apparatus that have needs for power amplifiers.

Such power amplifiers can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A power amplifier system comprising:
a cascode amplifier circuit configured to amplify a radio frequency signal when powered by a supply voltage and biased by a cascode driving voltage;
a supply source configured to provide the supply voltage; and
a cascode driving circuit configured to generate the cascode driving voltage based on the supply voltage, the cascode driving circuit including a first stage configured to provide a DC voltage, and a second stage configured to generate the cascode driving voltage that is tracking a level of the supply voltage based on the DC voltage.

2. The power amplifier system of claim 1 wherein the cascode amplifier circuit includes a first transistor and a second transistor disposed between the first transistor and a ground, the first transistor being disposed between the second transistor and an output node of the power amplifier system.

3. The power amplifier system of claim 2 wherein the cascode driving voltage is applied to the first transistor of the cascode amplifier circuit.

4. The power amplifier system of claim 2 wherein each of the first transistor and the second transistor of the cascode amplifier circuit is a bipolar junction transistor.

5. The power amplifier system of claim 1 wherein the second stage of the cascode driving circuit includes a current generator including a pair of transistors configured to generate a current tracking the level of the supply voltage.

6. The power amplifier system of claim 5 wherein the cascode driving voltage is determined by an amount of the generated current in addition to the DC voltage provided by the first stage of the cascode driving circuit.

7. The power amplifier system of claim 1 wherein the second stage of the cascode driving circuit includes an operational amplifier and a complementary metal oxide semiconductor field effect transistor connected to an output of the operational amplifier to be capable of tracking the level of the supply voltage.

8. The power amplifier system of claim 7 wherein the second stage includes an adjustable current source that provides power to the operational amplifier.

9. The power amplifier system of claim 8 wherein the adjustable current source is configured to generate a reference current based on a voltage supplying mode.

10. The power amplifier system of claim 9 wherein the voltage supplying mode is at least one of an average power tracking (APT) mode and an envelope tracking (ET) mode.

11. The power amplifier system of claim 10 wherein the adjustable current source is configured to generate a smaller reference current in APT mode than in ET mode.

12. A radio frequency module comprising:
a packaging board configured to receive a plurality of components; and
a power amplifier system implemented on the packaging board, the power amplifier system including a cascode amplifier circuit configured to amplify a radio frequency signal when powered by a supply voltage and biased by a cascode driving voltage, a supply source configured to provide the supply voltage, and a cascode driving circuit configured to generate the cascode driving voltage based on the supply voltage, the cascode driving circuit including a first stage configured to provide a DC voltage, and a second stage configured to generate the cascode driving voltage that is tracking a level of the supply voltage based on the DC voltage.

13. The radio frequency module of claim 12 wherein the radio frequency module is a front-end module.

14. The radio frequency module of claim 12 wherein the cascode amplifier circuit includes a first transistor and a second transistor disposed between the first transistor and a ground, the first transistor being disposed between the second transistor and an output node of the power amplifier system.

15. The radio frequency module of claim 14 wherein the cascode driving voltage is applied to the first transistor of the cascode amplifier circuit.

16. The radio frequency module of claim 14 wherein each of the first transistor and the second transistor of the cascode amplifier circuit is a bipolar junction transistor.

17. The radio frequency module of claim 12 wherein the second stage of the cascode driving circuit includes a current generator including a pair of transistors configured to generate a current tracking the level of the supply voltage.

18. The radio frequency module of claim 17 wherein the cascode driving voltage is determined by an amount of the generated current in addition to the DC voltage provided by the first stage of the cascode driving circuit.

19. The radio frequency module of claim 12 wherein the second stage of the cascode driving circuit includes an operational amplifier and a complementary metal oxide semiconductor field effect transistor connected to an output of the operational amplifier to be capable of tracking the level of the supply voltage.

20. The radio frequency module of claim 19 wherein the second stage includes an adjustable current source that provides power to the operational amplifier.
